(19) United States
(12) Patent Application Publication
(10) Pub. No.: US 2025/0089376 A1
(43) Pub. Date: Mar. 13, 2025

(54) ARRAY SUBSTRATE, DISPLAY PANEL AND ELECTRONIC DEVICE

(71) Applicant: KUNSHAN GO-VISIONOX OPTO-ELECTRONICS CO., LTD., Kunshan (CN)

(72) Inventors: Manman LI, Kunshan (CN); Chuanzhi XU, Kunshan (CN); Jintao LIU, Kunshan (CN); Siming HU, Kunshan (CN)

(73) Assignee: KUNSHAN GO-VISIONOX OPTO-ELECTRONICS CO., LTD., Kunshan (CN)

(21) Appl. No.: 18/957,909

(22) Filed: Nov. 25, 2024

(30) Foreign Application Priority Data
Dec. 29, 2023 (CN) 202311873131.6

(51) Int. Cl. H01L 27/12

(52) U.S. Cl. CPC H10D 86/60; H10D 86/441

(57) ABSTRACT

Provided are an array substrate, a display panel and an electronic device. The array substrate includes a first scanning line located on a first metal layer and a semiconductor wire located on a semiconductor active layer. The first scanning line includes a first metal wire segment extending in a first direction and at least one second metal wire segment extending in a second direction from the first metal wire segment, and the first direction intersects with the second direction. The semiconductor wire includes a first semiconductor wire segment extending in the second direction and a second semiconductor wire segment extending in the first direction, and the first semiconductor wire segment is connected to the second semiconductor wire segment. The orthographic projection of the first metal wire segment on a substrate overlaps the orthographic projection of the first semiconductor wire segment on the substrate.

### CROSS-REFERENCE TO RELATED APPLICATION

This application claims priority to Chinese Patent Application No. 202311873131.6 filed Dec. 29, 2023, the disclosure of which is incorporated herein by reference in its entirety.

### TECHNICAL FIELD

The present application relates to the field of display technology and, in particular, to an array substrate, a display panel and an electronic device.

### BACKGROUND

With the development of manufacturing technology of display devices, requirements for real device functions and display effects are becoming increasingly high. In some display devices, to improve the display effect, it is necessary to dispose different reset transistors and reset wires in pixel driving units of array substrates to reset anodes and gates of drive transistors respectively, resulting in corresponding adjustments on the arrangements of semiconductor wires and metal wires that form transistors and possibly affecting the overall display effect of display panels.

### SUMMARY

To overcome the preceding shortcomings in the related art, an object of the present application is to provide an array substrate. The array substrate includes a substrate, a semiconductor active layer located on one side of the substrate and a first metal layer located on one side of the semiconductor active layer away from the substrate.

The first metal layer includes a first scanning line. The first scanning line includes a first metal wire segment extending in a first direction and at least one second metal wire segment extending in a second direction from the first metal wire segment, and the first direction intersects with the second direction.

The semiconductor active layer includes a semiconductor wire, the semiconductor wire includes a first semiconductor wire segment extending in the second direction and a second semiconductor wire segment extending in the first direction, and the first semiconductor wire segment is connected to the second semiconductor wire segment.

An orthographic projection of the first metal wire segment on the substrate overlaps an orthographic projection of the first semiconductor wire segment on the substrate, and an orthographic projection of the at least one second metal wire segment on the substrate overlaps an orthographic projection of the second semiconductor wire segment on the substrate.

In an embodiment, the array substrate further includes a second metal layer located on one side of the first metal layer away from the substrate.

The second metal layer includes a shielding structure, and an orthographic projection of the shielding structure on the substrate covers an orthographic projection of a connection joint between the first semiconductor wire segment and the second semiconductor wire segment on the substrate.

In an embodiment, the first metal layer further includes a second scanning line adjacent to the first scanning line, where the second scanning line includes a third metal wire segment extending parallel to the first metal wire segment and at least one fourth metal wire segment extending in the second direction from the third metal wire segment, where the at least one second metal wire segment and the at least one fourth metal wire segment extend toward each other.

The semiconductor active layer further includes a third semiconductor wire segment extending in the second direction and a fourth semiconductor wire segment extending in the first direction, and the third semiconductor wire segment is connected to the fourth semiconductor wire segment.

An orthographic projection of the third metal wire segment on the substrate overlaps an orthographic projection of the third semiconductor wire segment on the substrate, and an orthographic projection of the at least one fourth metal wire segment on the substrate overlaps an orthographic projection of the fourth semiconductor wire segment on the substrate.

The orthographic projection of the shielding structure on the substrate further covers an orthographic projection of a connection joint between the third semiconductor wire segment and the fourth semiconductor wire segment on the substrate.

In an embodiment, the second semiconductor wire segment includes a first end portion and a second end portion arranged in the first direction, where the second end portion is connected to the first semiconductor wire segment.

The fourth semiconductor wire segment includes a third end portion and a fourth end portion arranged in the first direction, where the fourth end portion is connected to the third semiconductor wire segment.

The first end portion is connected to the second end portion through a fifth semiconductor wire segment extending in the second direction.

In an embodiment, the orthographic projection of the shielding structure on the substrate covers an orthographic projection of the first end portion on the substrate and an orthographic projection of at least part of the fifth semiconductor wire segment on the substrate.

Preferably, the third end portion is provided with a gate connection point, and the orthographic projection of the shielding structure on the substrate does not coincide with an orthographic projection of the gate connection point on the substrate.

In an embodiment, the shielding structure includes a first shielding portion, a second shielding portion and a third shielding portion connecting with the first shielding portion and the second shielding portion.

An orthographic projection of the first shielding portion on the substrate covers the orthographic projection of the first end portion on the substrate and the orthographic projection of the at least part of the fifth semiconductor wire segment on the substrate.

An orthographic projection of the second shielding portion on the substrate covers an orthographic projection of the second end portion on the substrate and an orthographic projection of the third end portion on the substrate.

An orthographic projection of the third shielding portion on the substrate is located between the orthographic projection of the at least one second metal wire segment on the substrate and the orthographic projection of the at least one fourth metal wire segment on the substrate that are opposite.

In an embodiment, the array substrate includes a plurality of rows of drive units arranged in the second direction, where one end of the first semiconductor wire segment of one row of the drive units away from the connection joint between the first semiconductor wire segment and the second semiconductor wire segment is connected to semiconductor wires in another row of drive units.

Preferably, the end of the first semiconductor wire segment of one row of the drive units away from the connection joint between the first semiconductor wire segment and the second semiconductor wire segment is provided with a reset voltage connection point, the reset voltage connection point is connected to the semiconductor wires in another row of the drive units.

In an embodiment, the array substrate includes a plurality of drive units, where each of the plurality of drive units includes a plurality of transistors, where a position at which the first metal wire segment overlaps the first semiconductor wire segment and a position at which the at least one second metal wire segment overlaps the second semiconductor wire segment form a first reset transistor having a double-gate structure, where the first reset transistor is configured to reset a voltage at a gate of a drive transistor in the plurality of drive units.

Preferably, a position at which the third metal wire segment overlaps the third semiconductor wire segment and a position at which the at least one fourth metal wire segment overlaps the fourth semiconductor wire segment form a threshold compensation transistor having a double-gate structure, where the threshold compensation transistor is configured to perform a threshold compensation on the voltage at the gate of the drive transistor in the plurality of drive units.

The present application further provides a display panel including the array substrate provided in the present application.

The present application further provides an electronic device including the display panel provided in the present application.

Compared with the related art, the present application has the beneficial effects below.

In the array substrate, the display panel and the electronic device provided in embodiments of the present application, performances of transistors formed by overlapping the first scanning line and the semiconductor wire can be improved by adjusting shapes of the semiconductor wire and the first scanning line.

For example, the length of a semiconductor wire in the transistors formed by overlapping the first scanning line and the semiconductor wire can be reduced, the voltage transmission distance on the semiconductor wire can be shortened, and the effectiveness and stability of voltage transmission can be ensured.

For another example, by adjusting the shapes of the semiconductor wire and the first scanning line, the semiconductor wire in the transistors formed by overlapping the first scanning line and the semiconductor wire can have sufficient space to overlap the shielding structure of the second metal layer to form a parasitic capacitance, thereby improving the operation performances of the transistors formed by overlapping the semiconductor wire and the first scanning line.

### BRIEF DESCRIPTION OF DRAWINGS

To illustrate technical solutions in embodiments of the present application more clearly, drawings used in the description of the embodiments are briefly described below. It is to be understood that the drawings described below illustrate part of the embodiments of the present application and are not construed as limiting the scope of the present application, and those of ordinary skill in the art may obtain other drawings based on the drawings described below on the premise that no creative work is done.

FIG. 1 is a diagram illustrating the layer structure of an array substrate according to this embodiment.

FIG. 2 is the first perspective view of wires of an array substrate according to this embodiment.

FIG. 3 is the second perspective view of wires of an array substrate according to this embodiment.

FIG. 4 is the third perspective view of wires of an array substrate according to this embodiment.

FIG. 5 is a diagram illustrating a drive unit circuit according to this embodiment.

FIG. 6 is the fourth perspective view of wires of an array substrate according to this embodiment.

FIG. 7 is the fifth perspective view of wires of an array substrate according to this embodiment.

FIG. 8 is the sixth perspective view of wires of an array substrate according to this embodiment.

FIG. 9 is a diagram illustrating a shielding structure according to this embodiment.

FIG. 10 is the seventh perspective view of wires of an array substrate according to this embodiment.

FIG. 11 is the eighth perspective view of wires of an array substrate according to this embodiment.

### DETAILED DESCRIPTION

To illustrate the object, the technical solutions and advantages of embodiments of the present application more clearly, the technical solutions of the embodiments of the present application are described clearly and completely in conjunction with the drawings of the embodiments of the present application. Apparently, the embodiments described below are part, not all, of the embodiments of the present application. Assemblies of the embodiments of the present applications described and illustrated in the drawings herein may generally be arranged and designed in various different configurations.

Therefore, the following detailed description of the embodiments of the present application provided in the drawings is not intended to limit the scope of the present application, but represents selected embodiments of the present application. Based on the embodiments of the present application, all other embodiments obtained by those of ordinary skill in the art without creative work are within the scope of the present application.

It is to be noted that similar reference numerals and letters indicate similar items in the following drawings, and therefore, once a particular item is defined in a drawing, the item does not require further definition and explanation in following drawings.

In the description of the present application, it is to be noted that orientations or positional relationships indicated by terms such as “center”, “above” “below”, “vertical”, “horizontal”, “inside” and “outside” are based on orientations or positional relationships illustrated in the drawings or orientations or positional relationship that products of the present application are usually used in. These orientations or positional relationships are for facilitating and simplifying the description of the present application and do not indicate or imply that an apparatus or element referred to must have a specific orientation and must be configured and operated in the specific orientation. Therefore, these orientations or positional relationships are not to be construed as limiting the present application. Moreover, terms such as “first”, “second” and “third” are used for distinguishing the description and are not to be construed as indicating or implying relative importance.

It is to be noted that if not in collision, different features in the embodiments of the present application may be combined with each other.

The present application provides an array substrate. The array substrate may include a substrate, a semiconductor active layer located on one side of the substrate and a first metal layer located on one side of the semiconductor active layer away from the substrate.

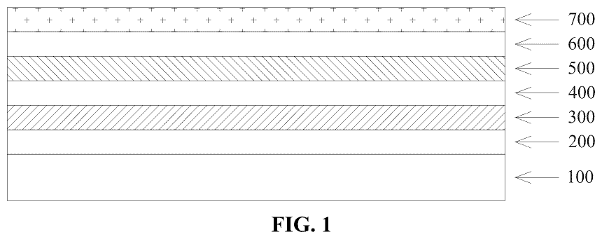

For example, referring to FIG. 1, a buffer layer 200 is disposed one side of the substrate 100, and the semiconductor active layer 300 may be disposed on one side of the buffer layer 200 away from the substrate 100.

A first insulating layer 400 is disposed on one side of the semiconductor active layer 300 away from the substrate 100, and the first metal layer 500 may be disposed on one side of the first insulating layer 400 away from the substrate 100. Optionally, the first insulating layer 400 may include a gate insulating layer.

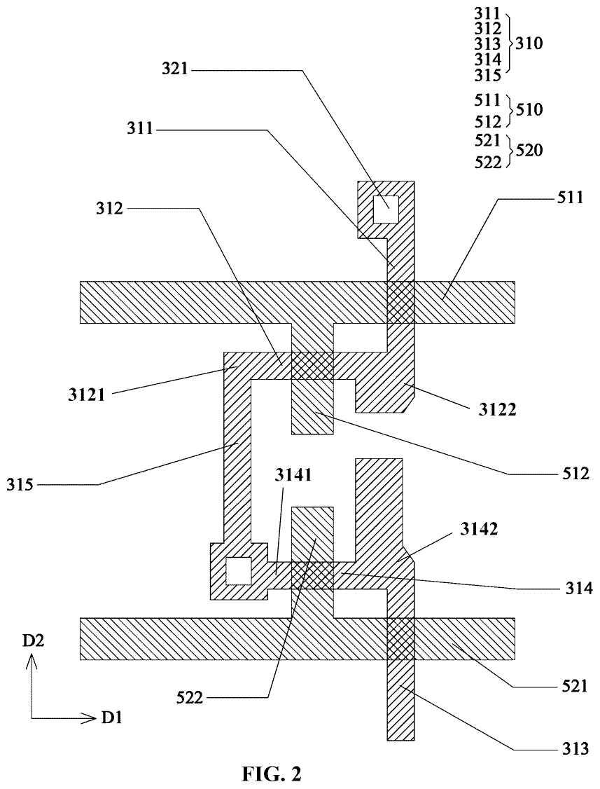

Referring to FIG. 2, FIG. 2 is a perspective view of the semiconductor active layer 300 and the first metal layer 500. The first metal layer 500 includes a first scanning line 510. The first scanning line 510 includes a first metal wire segment 511 extending in a first direction D1 and at least one second metal wire segment 512 extending in a second direction D2 from the first metal wire segment 511. The first direction D1 intersects with the second direction D2.

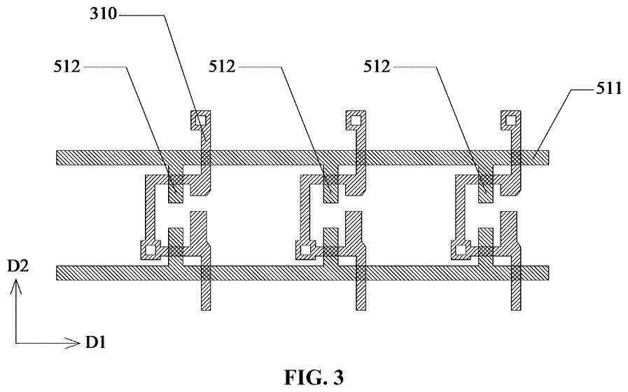

For example, the first direction D1 is vertical to the second direction D2, and one end of the second metal wire segment 512 may be connected to a middle portion of the first metal wire segment 511 to form a T-shaped structure. Optionally, referring to FIG. 3, the same first metal wire segment 511 may be connected to multiple second metal wire segments 512.

The semiconductor active layer 300 includes a semiconductor wire 310. The semiconductor wire 310 includes a first semiconductor wire segment 311 extending in the second direction D2 and a second semiconductor wire segment 312 extending in the first direction D1. The first semiconductor wire segment 311 is connected to the second semiconductor wire segment 312.

For example, one end of the first semiconductor wire segment 311 is connected to one end of the second semiconductor wire segment 312 to form an L-shaped structure.

The orthographic projection of the first metal wire segment 511 on the substrate 100 overlaps the orthographic projection of the first semiconductor wire segment 311 on the substrate 100, and the orthographic projection of the second metal wire segment 512 on the substrate 100 overlaps the orthographic projection of the second semiconductor wire segment 312 on the substrate 100.

For example, referring to FIG. 2, the L-shaped structure formed by the first semiconductor wire segment 311 and the second semiconductor wire segment 312 intersects the T-shaped structure formed by the first metal wire segment 511 and the second metal wire segment 512 to form two overlapped portions at which a transistor having a double-gate structure may be formed.

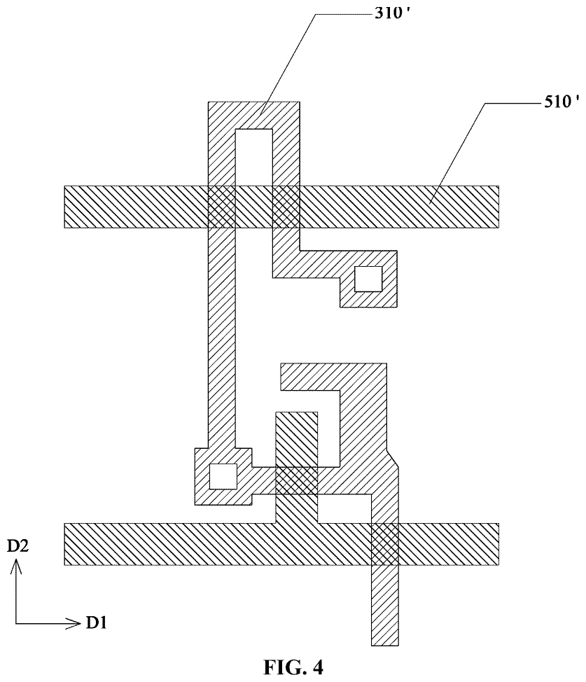

Based on the preceding design, referring to FIG. 4, compared with a semiconductor wire 310′ having an inverted U-shaped structure shown in FIG. 4 in some embodiments, in this embodiment, by adjusting shapes of the semiconductor wire 310 and the first scanning line 510, the length of a semiconductor wire 310 in transistors formed by overlapping the first scanning line 510 and the semiconductor wire 310 can be reduced, the voltage transmission distance on the semiconductor wire 310 can be shortened, and the effectiveness and stability of voltage transmission can be ensured.

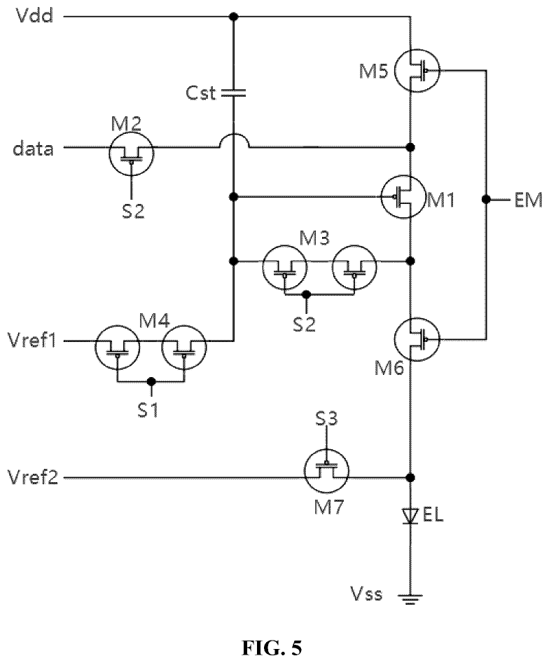

In an embodiment, the array substrate includes multiple drive units. Each drive unit includes multiple transistors. For example, referring to FIG. 5, the each drive unit may include a 7T1C circuit. To improve the display effect of a display panel driven by the array substrate, a first reset transistor M4 controlled by a first scanning signal S1 and a second reset transistor M7 controlled by a third scanning signal S3 are disposed in the 7T1C circuit to reset a gate of a drive transistor M1 and an anode of a light-emitting element EL respectively.

The first scanning line 510 provided in this embodiment may be configured to transmit the first scanning signal S1 shown in FIG. 5, and a position at which the first metal wire segment 511 overlaps the first semiconductor wire segment 311 and a position at which the second metal wire segment 512 overlaps the second semiconductor wire segment 312 may form the first reset transistor M4 having a double-gate structure. Referring to FIG. 2, one end of the second semiconductor wire segment 312 away from a connection joint between the second semiconductor wire segment 312 and the first semiconductor wire segment 311 may be provided with a reset voltage connection point. The reset voltage connection point is configured to connect to a reset voltage wire to receive a reset voltage Vref shown in FIG. 5.

In this case, the length of a semiconductor wire 310 from the reset voltage connection point to the gate of the drive transistor M1 can be shortened by adjusting the shapes of the semiconductor wire 310 and the first scanning line 510, thereby improving the reset effect.

In an embodiment, referring to FIG. 1, the array substrate further includes a second metal layer 700 located on one side of the first metal layer 500 away from the substrate 100. For example, a second insulating layer 600 is disposed on the side of the first metal layer 500 away from the substrate 100, and the second metal layer 700 may be disposed on one side of the second insulating layer 600 away from the substrate 100. Optionally, the second insulating layer 600 may include an interlayer insulating layer.

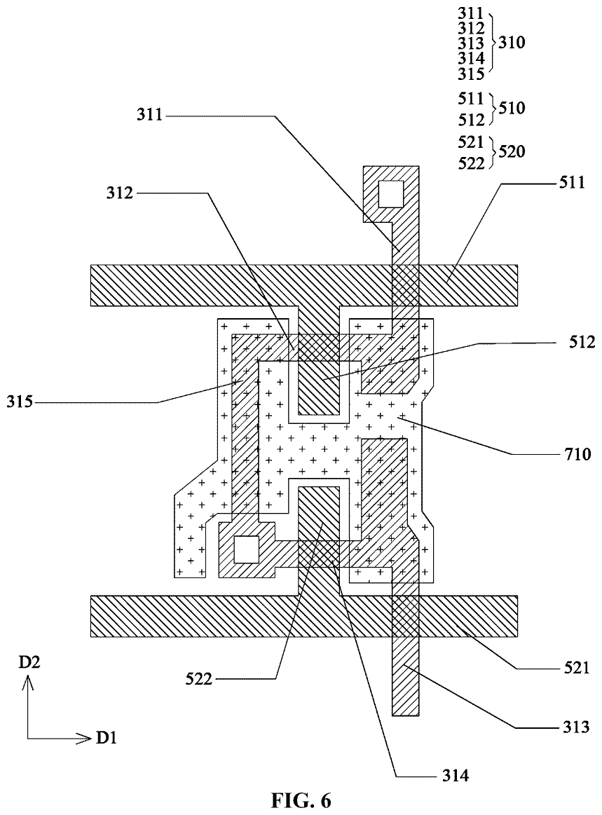

Referring to FIG. 6, the second metal layer 700 includes a shielding structure 710, and the orthographic projection of the shielding structure 710 on the substrate 100 covers the orthographic projection of the connection joint between the first semiconductor wire segment 311 and the second semiconductor wire segment 312 on the substrate 100.

In this manner, the semiconductor wire 310 in the transistors formed by overlapping the first scanning line 510 and the semiconductor wire 310 can have sufficient space to overlap the shielding structure 710 of the second metal layer 700 to form parasitic capacitance, thereby improving the operation performances of the transistors formed by overlapping the semiconductor wire 310 and the first scanning line 510.

For example, in the case where the first semiconductor wire segment 311 and the second semiconductor wire segment 312 overlap the first scanning line 510 to form the first reset transistor M4 shown in FIG. 5, enlarging the parasitic capacitance of the first reset transistor M4 can reduce the risk of a flickering screen on the display panel driven by the array substrate and improve the display effect of an always-on display (AOD) function.

In an embodiment, referring to FIG. 2, the first metal layer 500 further includes a second scanning line 520 adjacent to the first scanning line 510. The second scanning line 520 includes a third metal wire segment 521 extending parallel to the first metal wire segment 511 and at least one fourth metal wire segment 522 extending in the second direction D2 from the third metal wire segment 521. The at least one second metal wire segment 512 and the at least one fourth metal wire segment 522 extend toward each other. For example, the third metal wire segment 521 and each fourth metal wire segment 522 also form a T-shaped structure opposite to the T-shaped structure formed by the first metal wire segment 511 and the second metal wire segment 512.

The semiconductor active layer 300 further includes a third semiconductor wire segment 313 extending in the second direction D2 and a fourth semiconductor wire segment 314 extending in the first direction D1. The third semiconductor wire segment 313 is connected to the fourth semiconductor wire segment 314.

For example, the third semiconductor wire segment 313 and the fourth semiconductor wire segment 314 also form an L-shaped structure, and the direction of an opening of the L-shaped structure faces away from the direction of an opening of the L-shaped structure formed by the first semiconductor wire segment 311 and the second semiconductor wire segment 312.

The orthographic projection of the third metal wire segment 521 on the substrate 100 overlaps the orthographic projection of the third semiconductor wire segment 313 on the substrate 100, and the orthographic projection of the fourth metal wire segment 522 on the substrate 100 overlaps the orthographic projection of the fourth semiconductor wire segment 314 on the substrate 100.

For example, referring to FIG. 2, the L-shaped structure formed by the third semiconductor wire segment 313 and the fourth semiconductor wire segment 314 intersects the T-shaped structure formed by the third metal wire segment 521 and the each fourth metal wire segment 522 to form two overlaps at which another transistor having a double-gate structure may be formed.

In an embodiment, referring to FIG. 5, a threshold compensation transistor M3 controlled by a second scanning signal S2 is also disposed in the 7T1C circuit of the each drive unit and is configured to transmit a threshold voltage of the drive transistor M1 to the gate of the drive transistor M1.

The second scanning line 520 provided in this embodiment may be configured to transmit the second scanning signal S2 shown in FIG. 5, and a position at which the third metal wire segment 521 overlaps the third semiconductor wire segment 313 and a position at which the each fourth metal wire segment 522 overlaps the fourth semiconductor wire segment 314 may form the threshold compensation transistor M3 having a double-gate structure.

In an embodiment, referring to FIG. 6, the orthographic projection of the shielding structure 710 on the substrate 100 further covers the orthographic projection of a connection joint between the third semiconductor wire segment 313 and the fourth semiconductor wire segment 314 on the substrate 100.

That is, the orthographic projection of the same shielding structure 710 on the substrate 100 covers the orthographic projection of the connection joint between the first semiconductor wire segment 311 and the second semiconductor wire segment 312 on the substrate 100 and the orthographic projection of the connection joint between the third semiconductor wire segment 313 and the fourth semiconductor wire segment 314 on the substrate 100.

In this manner, the same shielding structure 710 may form parasitic capacitance with the transistor (such as the first reset transistor M4) formed by the first semiconductor wire segment 311 and the second semiconductor wire segment 312 and form parasitic capacitance with the transistor (such as the threshold compensation transistor M3) formed by the third semiconductor wire segment 313 and the fourth semiconductor wire segment 314 simultaneously. The parasitic capacitances can be further enlarged in the case of saving the wire space.

In an embodiment, referring to FIG. 2, the second semiconductor wire segment 312 includes a first end portion 3121 and a second end portion 3122 arranged in the first direction D1, and the second end portion is connected to the first semiconductor wire segment 311; the fourth semiconductor wire segment 314 includes a third end portion 3141 and a fourth end portion 3142 arranged in the first direction D1, and the fourth end portion is connected to the third semiconductor wire segment 313; and the first end portion 3121 is connected to the third end portion 3141 through a fifth semiconductor wire segment 315 extending in the second direction D2.

Further, referring to FIG. 6, the orthographic projection of the shielding structure 710 on the substrate 100 covers the orthographic projection of the first end portion 3121 on the substrate 100 and the orthographic projection of at least part of the fifth semiconductor wire segment 315 on the substrate 100. Preferably, the third end portion 3141 is provided with a gate connection point 323, and the orthographic projection of the shielding structure 710 on the substrate 100 does not coincide with, and does not cover the orthographic projection of the gate connection point 323 on the substrate 100.

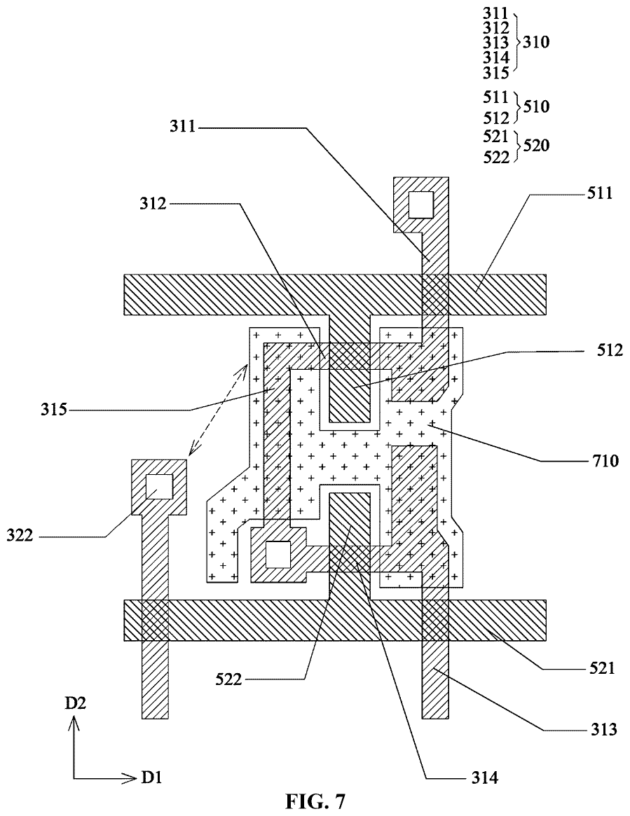

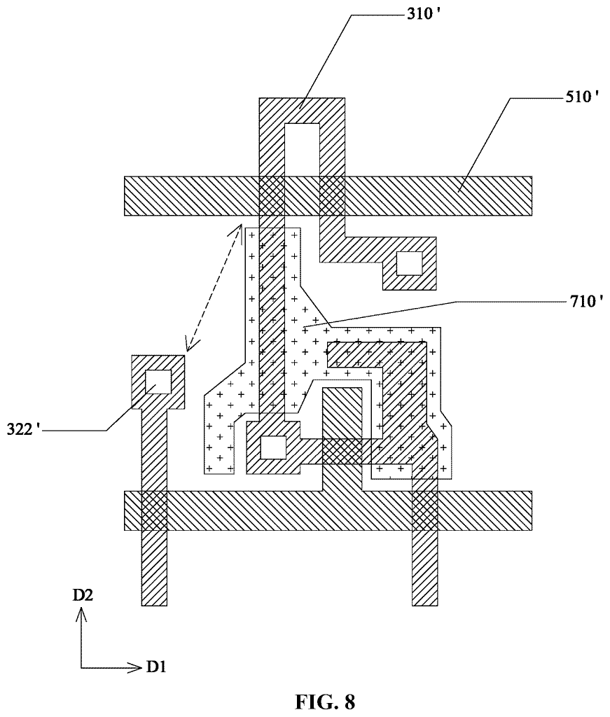

Referring to FIG. 7, in the first direction D1, in the semiconductor active layer 300, one side of the third end portion away from the fourth end portion is further provided with a data signal connection point 322. Based on the preceding design, one side of a semiconductor wire corresponding to the gate connection point 323 (such as the fifth semiconductor wire segment 315) facing the data signal connection point 322 can be better covered by the shielding structure 710. Compared with the solution in the related art as shown in FIG. 8 in which a shielding structure 710′ cannot completely cover one side of the semiconductor wire 310′ facing a data signal connection point 322′, the structure provided in this embodiment can better reduce the risk of signal crosstalk.

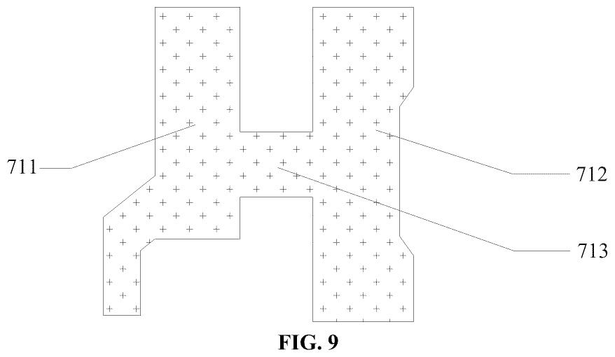

In an embodiment, referring to FIG. 9, the shielding structure 710 includes a first shielding portion 711, a second shielding portion 712 and a third shielding portion 713 connecting with the first shielding portion 711 and the second shielding portion 712.

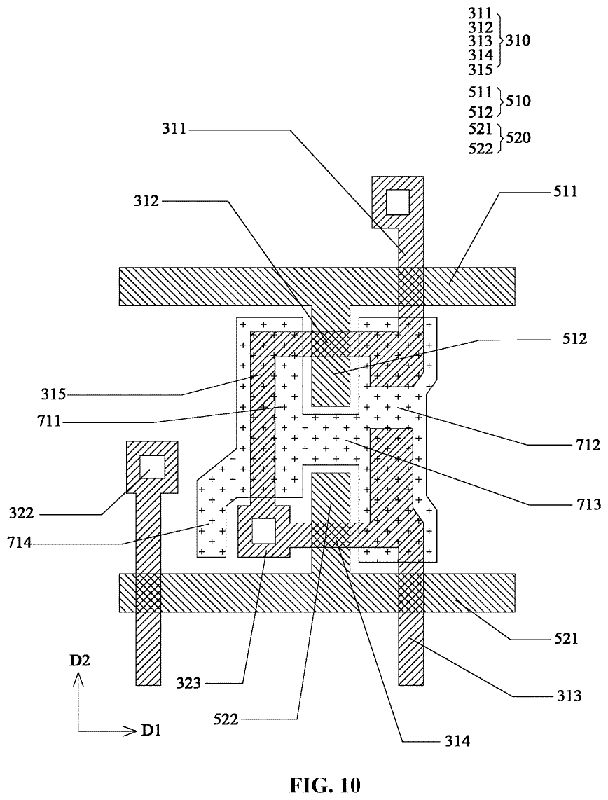

Referring to FIG. 10, the orthographic projection of the first shielding portion 711 on the substrate 100 covers the orthographic projection of the first end portion 3121 on the substrate 100 and the orthographic projection of the at least part of the fifth semiconductor wire segment 315 on the substrate 100; the orthographic projection of the second shielding portion on the substrate 100 covers the orthographic projection of the second end portion 3122 on the substrate 100 and the orthographic projection of the fourth end portion 3142 on the substrate 100; and the orthographic projection of the third shielding portion 713 on the substrate 100 is located between the orthographic projection of the second metal wire segment 512 on the substrate 100 and the orthographic projection of the each fourth metal wire segment 522 on the substrate 100.

In this manner, the third shielding portion can form better signal shielding between transistors formed by the second semiconductor wire segment 312 and the fourth semiconductor wire segment 314, thereby reducing the signal coupling influence between the first scanning line 510 and the second scanning line 520.

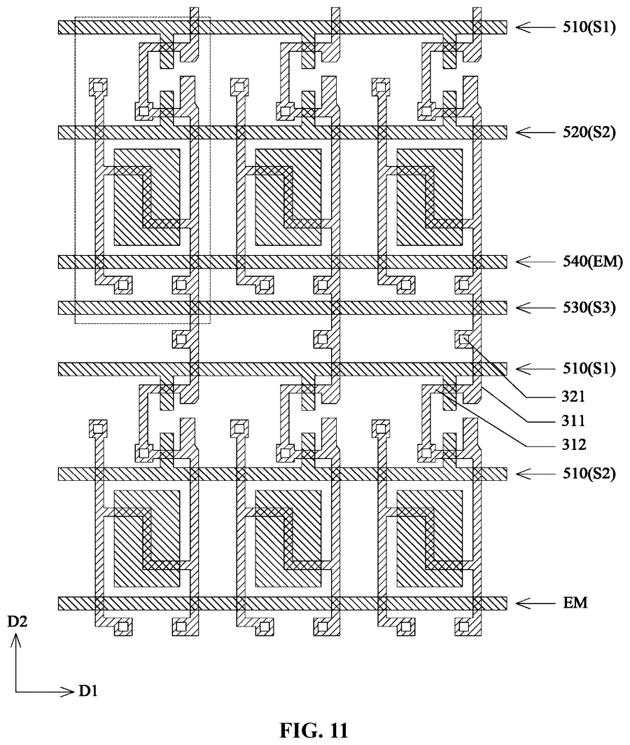

In an embodiment, referring to FIG. 11, the array substrate includes multiple rows of drive units arranged in the second direction D2 (which is shown in a dotted box in FIG. 11). One end of the first semiconductor wire segment 311 of one row of the drive units away from the connection joint between the first semiconductor wire segment 311 and the second semiconductor wire segment 312 is connected to semiconductor wires in another row of drive units. Preferably, the end of the first semiconductor wire segment 311 of one row of the drive units away from the connection joint between the first semiconductor wire segment 311 and the second semiconductor wire segment 312 is provided with a reset voltage connection point, and the reset voltage connection point is connected to the semiconductor wires in the another row of the drive units.

In this manner, in the second direction D2, semiconductor wires in the same column of drive units communicate with each other so that the difference in charges absorbed by semiconductor wires in the multiple drive units can be reduced, reducing an abnormal display risk caused by static electricity.

Moreover, referring to FIG. 11, besides the first scanning line 510 and the second scanning line 520, the first metal layer 500 further includes a light emission control signal line 540 configured to transmit a light emission control signal EM shown in FIG. 5, a third scanning line 530 configured to transmit the third scanning signal S3 shown in FIG. 5 and others. Details are not described herein.

The present application further provides a display panel including the array substrate provided in the present application.

The present application further provides an electronic device including the display panel provided in the present application.

In conclusion, in the array substrate, the display panel and the electronic device provided in the embodiments of the present application, the operation performances of the transistors formed by overlapping the first scanning line and the semiconductor wire can be improved by adjusting the shapes of the semiconductor wire and the first scanning line.

The technical features of the preceding embodiments may be combined in any way. For the brevity of description, all possible combinations of the technical features in the preceding embodiments are not described. However, as long as the combinations of these technical features do not conflict, these combinations should be considered be within the scope of the specification.

The preceding embodiments are several embodiments of the present application, and the specific and detailed description thereof cannot be understood as limiting the scope of the present application. It is to be noted that for those of ordinary skill in the art, several modifications and improvements can be made without departing from the concept of the present application, and these modifications and improvements are within the scope of the present application. Therefore, the scope of protection of the present application is defined by the appended claims.

What is claimed is:

1. An array substrate, comprising:
a substrate;
a semiconductor active layer located on one side of the substrate; and
a first metal layer located on one side of the semiconductor active layer away from the substrate, the first metal layer comprising a first scanning line, the first scanning line comprising a first metal wire segment extending in a first direction and at least one second metal wire segment extending in a second direction from the first metal wire segment, the first direction intersecting with the second direction;
wherein the semiconductor active layer comprises a semiconductor wire, the semiconductor wire comprises a first semiconductor wire segment extending in the second direction and a second semiconductor wire segment extending in the first direction, and the first semiconductor wire segment is connected to the second semiconductor wire segment; and
wherein an orthographic projection of the first metal wire segment on the substrate overlaps an orthographic projection of the first semiconductor wire segment on the substrate, and an orthographic projection of the at least one second metal wire segment on the substrate overlaps an orthographic projection of the second semiconductor wire segment on the substrate.

2. The array substrate of claim 1, further comprising:
a second metal layer located on one side of the first metal layer away from the substrate,
wherein the second metal layer comprises a shielding structure, and an orthographic projection of the shielding structure on the substrate covers an orthographic projection of a connection joint between the first semiconductor wire segment and the second semiconductor wire segment on the substrate.

3. The array substrate of claim 2, wherein the first metal layer further comprises a second scanning line disposed adjacent to the first scanning line, the second scanning line comprises a third metal wire segment extending parallel to the first metal wire segment and at least one fourth metal wire segment extending in the second direction from the third metal wire segment, and the at least one second metal wire segment and the at least one fourth metal wire segment extend toward each other;
wherein the semiconductor active layer further comprises a third semiconductor wire segment extending in the second direction and a fourth semiconductor wire segment extending in the first direction, and the third semiconductor wire segment is connected to the fourth semiconductor wire segment;
an orthographic projection of the third metal wire segment on the substrate overlaps an orthographic projection of the third semiconductor wire segment on the substrate, and an orthographic projection of the at least one fourth metal wire segment on the substrate overlaps an orthographic projection of the fourth semiconductor wire segment on the substrate; and
the orthographic projection of the shielding structure on the substrate further covers an orthographic projection of a connection joint between the third semiconductor wire segment and the fourth semiconductor wire segment on the substrate.

4. The array substrate of claim 3, wherein the second semiconductor wire segment comprises a first end portion and a second end portion arranged in the first direction, wherein the second end portion is connected to the first semiconductor wire segment;
the fourth semiconductor wire segment comprises a third end portion and a fourth end portion arranged in the first direction, and the fourth end portion is connected to the third semiconductor wire segment; and
the first end portion is connected to the third end portion through a fifth semiconductor wire segment extending in the second direction.

5. The array substrate of claim 4, wherein the orthographic projection of the shielding structure on the substrate covers an orthographic projection of the first end portion on the substrate and an orthographic projection of at least part of the fifth semiconductor wire segment on the substrate.

6. The array substrate of claim 4, wherein the third end portion is provided with a gate connection point, and the orthographic projection of the shielding structure on the substrate does not coincide with an orthographic projection of the gate connection point on the substrate.

7. The array substrate of claim 5, wherein the shielding structure comprises a first shielding portion, a second shielding portion and a third shielding portion connecting with the first shielding portion and the second shielding portion;
an orthographic projection of the first shielding portion on the substrate covers the orthographic projection of the first end portion on the substrate and the orthographic projection of the at least part of the fifth semiconductor wire segment on the substrate;
an orthographic projection of the second shielding portion on the substrate covers an orthographic projection of the second end portion on the substrate and an orthographic projection of the fourth end portion on the substrate; and
an orthographic projection of the third shielding portion on the substrate is located between the orthographic projection of the at least one second metal wire segment on the substrate and the orthographic projection of the at least one fourth metal wire segment on the substrate.

8. The array substrate of claim 2, further comprising a plurality of rows of drive units arranged in the second direction, one end of the first semiconductor wire segment of one row of the drive units away from the connection joint between the first semiconductor wire segment and the second semiconductor wire segment is connected to semiconductor wires in another row of drive units.

9. The array substrate of claim 8, wherein the end of the first semiconductor wire segment of one row of the drive units away from the connection joint between the first semiconductor wire segment and the second semiconductor wire segment is provided with a reset voltage connection point, the reset voltage connection point is connected to the semiconductor wires in another row of the drive units.

10. The array substrate of claim 1, further comprising a plurality of drive units, wherein each of the plurality of drive units comprises a plurality of transistors, a position at which the first metal wire segment overlaps the first semiconductor wire segment and a position at which the at least one second metal wire segment overlaps the second semiconductor wire segment form a first reset transistor having a double-gate structure, and the first reset transistor is configured to reset a voltage at a gate of a drive transistor in the plurality of drive units.

11. The array substrate of claim 3, wherein a position at which the third metal wire segment overlaps the third semiconductor wire segment and a position at which the at least one fourth metal wire segment overlaps the fourth semiconductor wire segment form a threshold compensation transistor having a double-gate structure, wherein the threshold compensation transistor is configured to perform a threshold compensation on the voltage at the gate of the drive transistor in the plurality of drive units.

12. A display panel, comprising the array substrate of claim 1.

13. An electronic device, comprising the display panel of claim 12.
